(19) United States
(12) Patent Application Publication
(10) Pub. No.: US 2018/0192520 A1
(43) Pub. Date: Jul. 5, 2018

(54) STRETCHABLE ELECTRONIC SYSTEM BASED ON CONTROLLED BUCKLED FLEXIBLE PRINTED CIRCUIT BOARD (PCB)

(71) Applicant: INTEL CORPORATION, Santa Clara, CA (US)

(72) Inventors: Chwee Lin CHOONG, Paya Terubung (MY); Kheng Tat MAR, Air Itam (MY)

(21) Appl. No.: 15/394,501

(22) Filed: Dec. 29, 2016

(51) Int. Cl. H05K 1/18; H05K 1/02; H05K 3/46; H05K 1/11; H05K 1/14; H01L 23/498; H01L 23/31; H05K 3/28; H01L 21/56; H05K 3/32; H01L 21/48

(52) U.S. Cl. CPC H05K 1/189; H05K 2203/1316; H05K 3/4691; H05K 3/4644; H05K 1/111; H05K 1/144; H05K 3/4611; H01L 23/49838; H01L 23/4985; H01L 23/3121; H01L 23/49833; H05K 3/284; H01L 21/56; H05K 3/32; H01L 21/4846; H05K 2201/10674; H05K 2201/09263; H05K 2203/1327; H05K 1/0283

(57) ABSTRACT

A microelectronic device system and a method of forming a microelectronic device are described. The microelectronic device includes a flex printed circuit board (PCB) having two or more electrical sub-systems that are electrically coupled by a plurality of conductive traces, where the flex PCB may be a buckled flex PCB. The microelectronic device includes a plurality of anchoring sites formed on a backside surface of the flex PCB. The microelectronic device encapsulates an elastomer over the flex PCB, the electrical sub-systems, and the conductive traces. The microelectronic device may stretch in a unidirectional and bidirectional axis. The microelectronic device may have electronic components attached to the electrical sub-systems. The microelectronic device may have stretchable segments where each of the stretchable segments is formed between a pair of anchoring sites. The microelectronic device may have three-dimensional (3D) conductive traces, where the 3D conductive traces are 3D meandering traces.

### FIELD

Embodiments relate to semiconductor devices. More particularly, the embodiments relate to packaging semiconductor devices on a stretchable electronic system with a buckled flexible PCB that includes three-dimensional (3D) meandering traces.

### BACKGROUND

Healthcare wearables struggle for accurate measurement of vital signs such as heart rate, blood pressure, body temperature, and oxygen saturation. This is partly attributed to the inelasticity of the wearables that prevent the sensors from conforming with the body parts being monitored.

Electronic devices, for example, are increasingly being incorporated into flexible and wearable products. Medical sensors, media players, personal computers, or similar applications are being integrated into wearable materials, such as medical bands/straps, shirts, watches, caps, or other compliant products. Electronics are typically incorporated into a flexible and wearable product that includes electrical components that are connected to conductive traces on a non-buckled flex PCB. This non-buckled flex PCB provides a considerable degree of bendability, but it cannot be stretched. FIGS. 1A and 1B illustrate these problems.

FIG. 1A is a cross-sectional view of a typical flexible electronic system 100. The typical flexible electronic system 100 can bend but is unable to stretch. The typical flexible electronic system 100, therefore, cannot self-adjust and tailor to wearables of different sizes or shapes. The flexible electronic system 100 includes a non-buckled flex PCB 101 (also referred to as a planar flex PCB) and electronic components 102, such as silicon dies and packages. The planar flex PCB 101 includes straight conductive traces 104 that are electrically connecting two electrical sub-systems 103, as illustrated in FIG. 1B. Each of the electrical sub-systems 103 is a rigid pad that is mounted on the planar flex PCB 101. The electrical sub-systems 103 are used to attach one or more electrical components 102 onto the rigid pad.

Typically, the most common approach to make a flexible electronic system stretchable is wiring rigid electronic components (e.g., electric components 102) with stretchable interconnects, such as two-dimensional (2D) and 3D meandering metallic conductive traces. The 2D meandering traces, however, occupy a large amount of routing space and lack mechanical elasticity. As such, a major disadvantage of 2D meandering traces is that it limits the frequency of the interconnect lines and reduces trace density.

Another common approach is the application of 3D meandering traces (or wavy/buckled interconnects) at a device level to form stretchable interconnects. A major disadvantage of integrating 3D meandering traces at a device level—rather than at a system level—includes a relatively complicated microfabrication process, which includes rigid substrate thinning, transfer printing, and micromachining.

### BRIEF DESCRIPTION OF THE DRAWINGS

Embodiments described herein illustrated by way of example and not limitation in the figures of the accompanying drawings, in which like references indicate similar features. Furthermore, some conventional details have been omitted so as not to obscure from the inventive concepts described herein.

FIG. 1A is a cross-sectional view of a typical flexible electronic system that includes a non-buckled flex PCB and electronic components, according to one embodiment.

FIG. 1B is a plan view of a typical flexible electronic system that includes a non-buckled flex PCB, electronic sub-systems, conductive traces, and electronic components, according to one embodiment.

FIG. 2A is a cross-sectional view of a unidirectional stretchable electronic system at a non-stretched position that includes a buckled flex PCB with 3D meandering traces and a plurality of anchoring points, according to one embodiment.

FIG. 2B is a cross-sectional view of a unidirectional stretchable electronic system at a stretched position that includes a buckled flex PCB with 3D meandering traces and a plurality of anchoring points, according to one embodiment.

FIG. 2C is a plan view of a unidirectional stretchable electronic system at a stretched position that includes a buckled flex PCB with 3D meandering traces and a plurality of anchoring points, according to one embodiment.

FIGS. 3 and 5A are plan views of a method of forming a stretchable electronic system that includes a buckled flex PCB with selective anchoring sites, according to one embodiment.

FIGS. 4-5B and 6-10 are cross-sectional views of a method of forming a stretchable electronic system that includes a buckled flex PCB embedded in an elastomer, according to one embodiment.

FIG. 11 is a process flow illustrating a method of forming a stretchable electronic system that includes a buckled flex PCB embedded in an elastomer, according to one embodiment.

FIG. 12A is a plan view of a backside of a bidirectional stretchable electronic system with selective anchoring sites and fixed-pitch anchored stretchable segments, according to one embodiment.

FIG. 12B is a plan view of a bidirectional stretchable electronic system at a stretched position that includes four electronic sub-systems connected with conductive traces embedded in an elastomer, according to one embodiment.

FIG. 13A is a plan view of a backside of an alternative bidirectional stretchable electronic system with selective anchoring sites and fixed-pitch anchored stretchable segments, according to one embodiment.

FIG. 13B is a plan view of an alternative bidirectional stretchable electronic system at a stretched position that includes five electronic sub-systems connected with conductive traces embedded in an elastomer, according to one embodiment.

FIG. 14 is a cross-sectional view of a 3D stacked (or folded) stretchable electronic system that includes two buckled flex PCBs with 3D meandering traces connected using vertical endpoints, according to one embodiment.

FIG. 15A is a plan view of a backside of a stretchable electronic system with fixed-pitch anchoring sites on a pre-strained elastomer, according to one embodiment.

FIG. 15B is a cross-sectional view of a stretchable electronic system illustrating one or more parameters of fixed-itch anchoring pattern on a pre-strained elastomer, according to one embodiment.

FIG. 16 is a cross-sectional view of a stretchable electronic system at a non-stretched position that includes one or more parameters of a buckled flex PCB with 3D meandering traces after strain relaxation, according to one embodiment.

FIG. 17 is a graph illustrating a pre-strained elastomer using a stretchable electronic system, according to one embodiment.

FIG. 18 is a graph illustrating a non-anchored length of a periodic anchoring pattern using a stretchable electronic system, according to one embodiment.

FIG. 19 is a graph illustrating an anchored length of a periodic anchoring pattern using a stretchable electronic system, according to one embodiment.

FIG. 20 is a schematic block diagram illustrating a computer system that utilizes a stretchable electronic system, according to one embodiment.

### DETAILED DESCRIPTION

Described below are stretchable electronic systems based on a controlled bucked flexible (flex) printed circuit board (PCB) (hereinafter “flex PCB”). Systems of stretchable microelectronic devices and methods of forming the stretchable microelectronic devices are described. The stretchable microelectronic systems are applicable at a system level for electrical packaging technologies. For one embodiment, a three-dimensional (3D) buckled flex PCB (or a 3D wavy flex PCB) including 3D meandering traces (or standing wavy interconnects) forms a stretchable electronic system with elastic properties.

Embodiments of the buckled flex PCB help to enable a buckling structure with stretchy, high-density 3D meandering traces. In addition, embodiments of the buckled flex PCB also help to facilitate healthcare wearables with elastic properties (i.e., rubber band-like properties) in order to self-adjust and tailor to users of different sizes and body parts of various shapes.

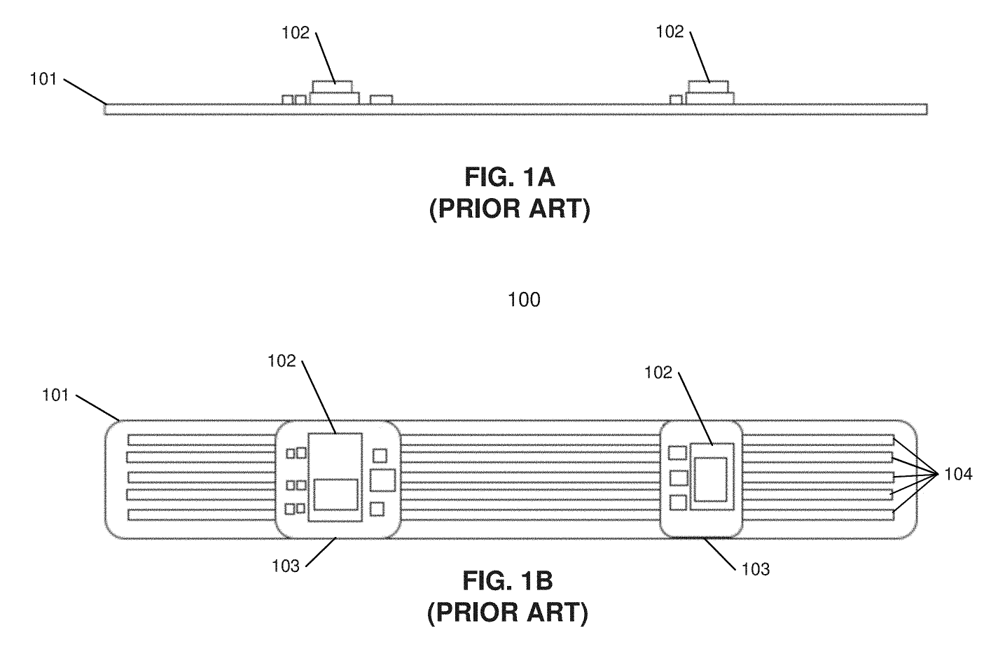

Embodiments of the buckled flex PCB also enhance packaging solutions by enabling integration at a system level during PCB assembly rather than at a device level. The buckled flex PCB is formed at a system level using a planar flex PCB (e.g., planar flex PCB 101 of FIG. 1) that is not stretchable.

To exhibit elasticity and a stretching ability, a method of forming stretchable electronic systems is described to transform the planar flex PCB into a buckled flex PCB encapsulated in an elastomer. The buckled flex PCB can therefore reversibly arch and straighten with the movement of the elastomer. This packaging solution of the buckled flex PCB at the system level, therefore, results in better yield, shorter development time, and faster time-to-market.

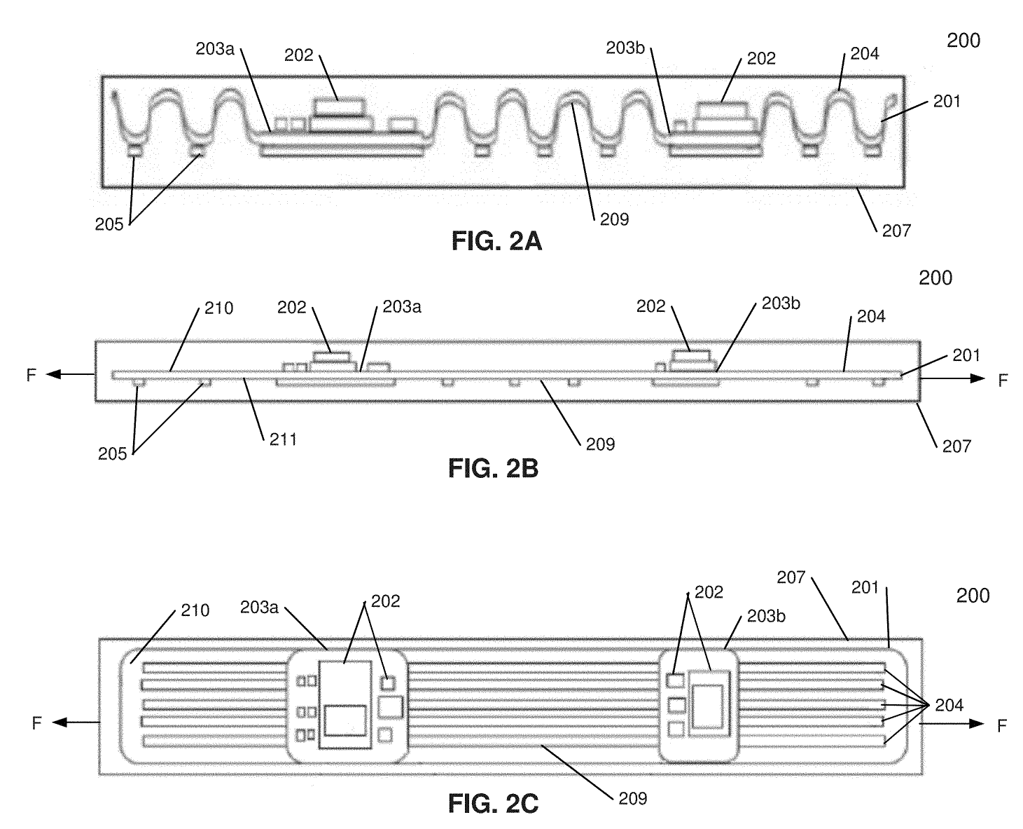

FIGS. 2A-C show a unidirectional stretchable electronic system 200 at a non-stretched position as shown in FIG. 2A, and a stretched position as shown in FIG. 2B. FIGS. 2A-C illustrate stretchable electronic system 200 that includes a buckled flex PCB 201. As used herein, a “stretchable electronic system” (also referred to as a stretchable microelectronic system or device) refers to a flexible PCB (or a stretchable substrate) that has a compliant material which allows the system to stretch, flex, bend, twist, etc. For example, the stretchable electronic system may be used in medical wearables to accurately measure vital signs of patients, such as heart rate, blood pressure, body temperature, oxygen saturation, etc. The stretchable electronic system provides elasticity to the wearables in order to help the sensors conform to the body parts being monitored. As such, the stretchable electronic system has elastic properties that enable the system to self-adjust and tailor to wearables of different sizes and shapes.

As used herein, a “flex PCB” refers to a flexible printed circuit board (also referred to as flex circuits, flexible PCBs, flex print, flexi-circuits, etc.). A flex PCB may be used to assemble electronic circuits (or integrated circuits (ICs)) by mounting electronic devices (or IC components) on a flexible plastic substrate (i.e., a stretchable substrate), such as an elastomer (also referred to as an elastic polymer), a polyimide, a polyether ether ketone (PEEK), or a transparent conductive polyester film. For example, the flex PCB as described below may have a thin insulating polymer film with conductive circuit patterns affixed thereto, and it may be formed with a thin polymer coating to protect the electric circuits and components. For one embodiment, the compliant nature of the flex PCB may be attributable to a low modulus, and the flex PCB may be polydimethylsiloxane (PDMS) or polyurethane.

Referring now to FIG. 2A, stretchable electronic system 200 includes buckled flex PCB 201, electrical components 202, electrical sub-systems 203a-b, 3D meandering traces 204 (also referred to as 3D meandering interconnects), anchoring sites 205 (also referred to as anchoring points), elastomer 207, and stretchable segments 209. As used herein, a “buckled” flex PCB refers to a 3D wavy flex PCB as shown in FIG. 2A that includes 3D meandering traces 204 (or standing wavy interconnects) used to create stretchable electronic system 200.

Buckled flex PCB 201 may be formed from a planar flex PCB (e.g., planar flex PCB 101 of FIG. 1) having conductive traces embedded in a plastic dielectric material. For one embodiment, the conductive traces of the planar flex PCB are transformed into 3D meandering traces/interconnects 204 using a selective anchoring process.

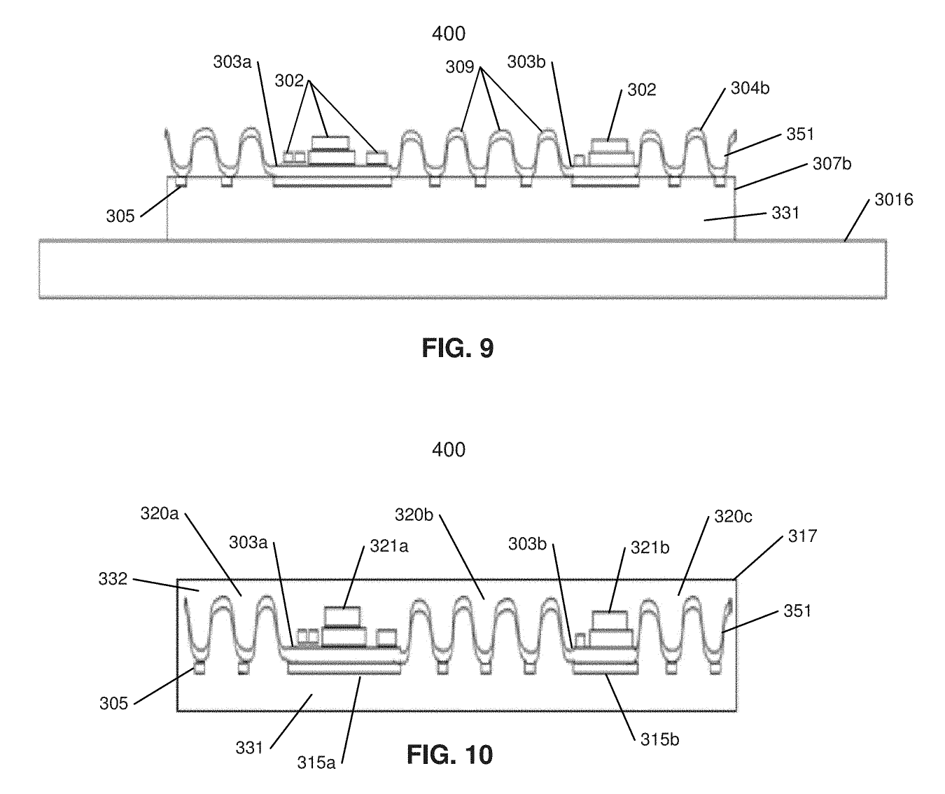

The selective anchoring process described herein includes (i) selectively anchoring the planar flex PCB to pre-strained elastomer 207 at selective anchoring sites 205 (as shown in FIG. 5A), and then (ii) relaxing the strain in elastomer 207 to form stretchable segments 209 (i.e., buckling structures) on the buckled flex PCB 201 (as shown in FIGS. 9-10). For one embodiment, anchoring sites 205 may include, but are not limited to, adhesives, adhesive precursors, welds, or photo-curable polymers.

3D meandering traces 204 may electrically couple electrical sub-systems 203a-b. The 3D meandering traces 204 may be formed from any commonly used conductive material for interconnect lines. For example, 3D meandering interconnects 204 may include, but not limited to, copper, silver, gold, or alloys thereof. For some embodiments, 3D meandering traces 204 are a conductive stack of materials, such as, but not limited to adhesion promoters, seed layers, and oxidation inhibitors. Note that 3D meandering traces 204 may be formed with typical interconnect formation processes known in the art, such as damascene processing, printing, or the like.

For some embodiments, stretchable segments 209 are formed with 3D meandering traces/interconnects 204. Each of the stretchable segments 209 provides a buckling structure between anchoring sites 205 to enable stretchability. To form the buckling structure of stretchable segments 209, for example, the buckled flex PCB 201 is partially anchored to the pre-strained elastomer 207 (or stretched elastomer) with anchoring sites 205 spaced at selected intervals along the length of the buckled flex PCB 201. When the pre-strain elastomer 207 is relaxed, the stretchable segments 209 (i.e., the non-anchored flex PCB regions) will delaminate from elastomer 207 and thus form an arch (or a buckle) between every pair of anchoring sites 205, as shown in FIG. 2A.

Stretchable segments 209 may also include one or more small components (not shown) embedded in the buckled flex PCB 201. For one embodiment, stretchable segments 209 of the buckled flex PCB 201 can be formed thinner than the rigid pads of electrical sub-systems 203a-b, such as using an adhesiveless laminate (not shown) to reduce the bending strain occurring at the buckling wave peak and thus enhancing the elasticity of the stretchable electronic system 200. For alternate embodiments, 3D meandering traces 204 experience negligible bending strain in the buckling form by constructing the conductive traces in the neutral mechanical plane of the flex PCB, which is generally located on the central plane of the material stack. For example, this neutral-bend axis is vital to the flexible circuit design in order to reduce the bending strain.

Elastomer 207 may also be referred to as a pre-strained elastomer when it is stretched and/or a non-strained elastomer when it is relaxed. For some embodiments, elastomer 207 allows the buckled flex PCB 201 to reversibly arch and straighten with the movement of the elastomer 207. For some embodiments, elastomer 207 encapsulates buckled flex PCB 201 to enable viscoelasticity and allow the buckled flex PCB 201 to maintain its stretchability.

In addition, stretchable electronic system 200 includes two electrical sub-systems 203a and 203b connected to each other via 3D meandering traces 204. For one embodiment, stretchable segments 209 with 3D meandering traces 204 are used to electrically connect electrical sub-systems 203a and 203b. Each of the electrical sub-systems 203a-b includes a rigid pad (or a rigid segment) that has no buckling structures and absorbs increased mechanical strains.

Each of the electrical sub-systems 203a-b may include one or more electrical components 202 that are mounted or embedded in the buckled flex PCB 201. For one embodiment, electrical components 202 may include a plurality of IC components, such as electrical devices, semiconductor dies, packages, substrates, microelectromechanical system (MEMS), or any combination thereof. For example, the electrical devices may include one or more of a processor, a memory component, a sensor, a MEMS, or the like, or any combination thereof. For one embodiment, the semiconductor dies may be a system-on-a-chip (SoC).

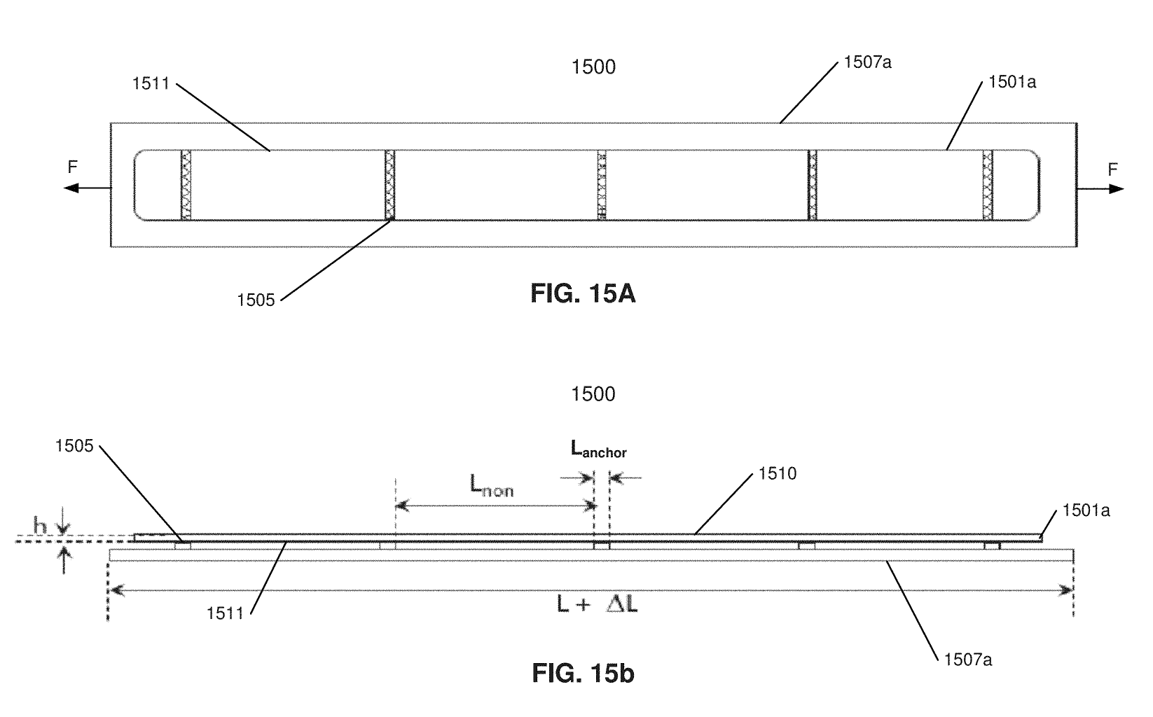

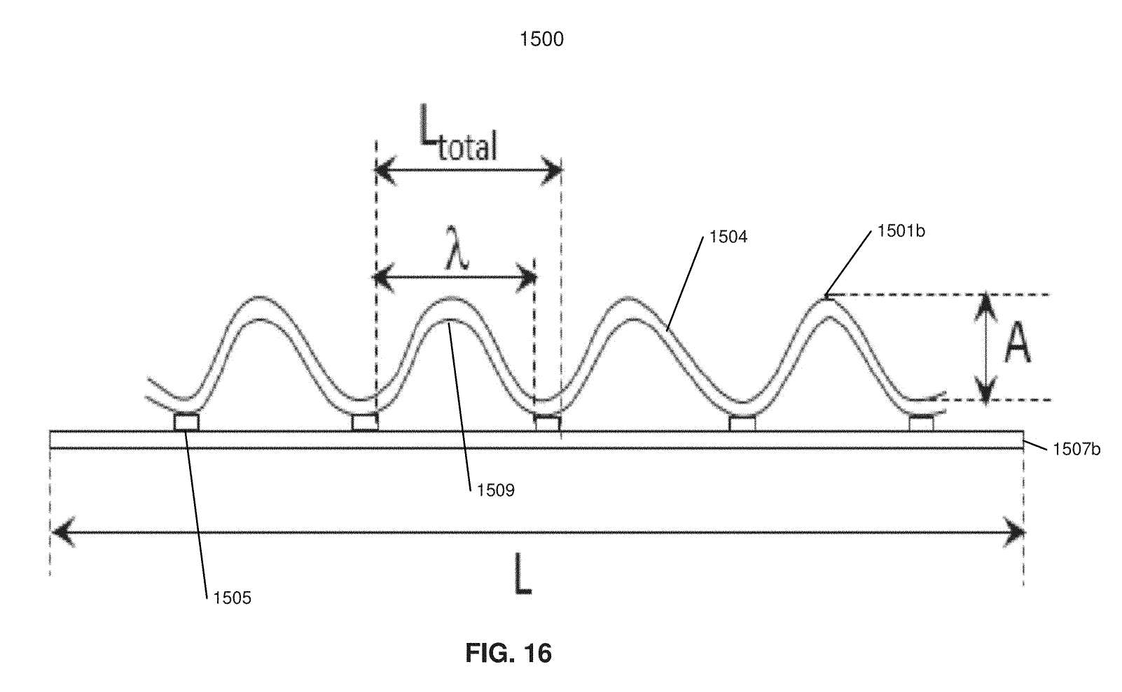

Note that FIG. 2A illustrates stretchable electronic system 200 having a smaller (or shorter) length at a non-stretched (shorter) state, while the stretchable electronic system 200 of FIGS. 2B-C have a larger (or longer) length at a stretched (longer) state. For example, as described below in further detail in FIGS. 15-16, stretchable electronic system 200 of FIG. 2A has a non-stretched length (L) that has a shorter length, where L is the original length of the elastomer without stretching (or pre-straining); meanwhile the stretchable electronic system 200 of FIGS. 2B-C have a stretched/pre-stretched length (L+ΔL) that have a longer length.

FIG. 2B is a cross-sectional view of unidirectional stretchable electronic system 200 at a stretched position as indicated by the arrows F. Meanwhile, FIG. 2C is a plan view of the unidirectional stretchable electronic system 200 at a stretched position.

FIG. 2B illustrates the stretchable electronic system 200 of FIG. 2A having a frontside surface 210 of the buckled flex PCB 201 and a backside surface 211 of the buckled flex PCB 201.

Stretchable electronic system 200 is stretched unidirectionally as indicated by arrows F. Further, buckled flex PCB 201 of FIG. 2B shows that the buckling structures have straighten out to accommodate stretching along arrows F, as such the electrical connectivity through the 3D meandering traces 204 is sustained despite the stretching induced by the system.

For some embodiments, anchoring sites 205 are formed and patterned over backside surface 211 of buckled flex PCB 201. For example, anchoring sites 205 are formed and patterned via the selective anchoring process in order to define both rigid segments (e.g., electrical sub-systems 203a-b) and stretchable segments (e.g., stretchable segments 209) of the buckled flex PCB 201. For example, a hard overmold layer (not shown) may be formed over the electrical sub-systems 203a-b and electrical components 202 to enhance the robustness of these rigid segments.

FIG. 2C shows the two electrical sub-systems 203a-b electronically connected with 3D meandering interconnects 204. Further, as shown in FIG. 2C, each of the electrical sub-systems 203a-b may include a semiconductor die, a package, and one or more IC components. Note that as shown in FIGS. 2A-C, elastomer 207 encapsulates the buckled flex PCB 201 to further enhance the stretchability and viscoelastic properties of the stretchable electronic system 200.

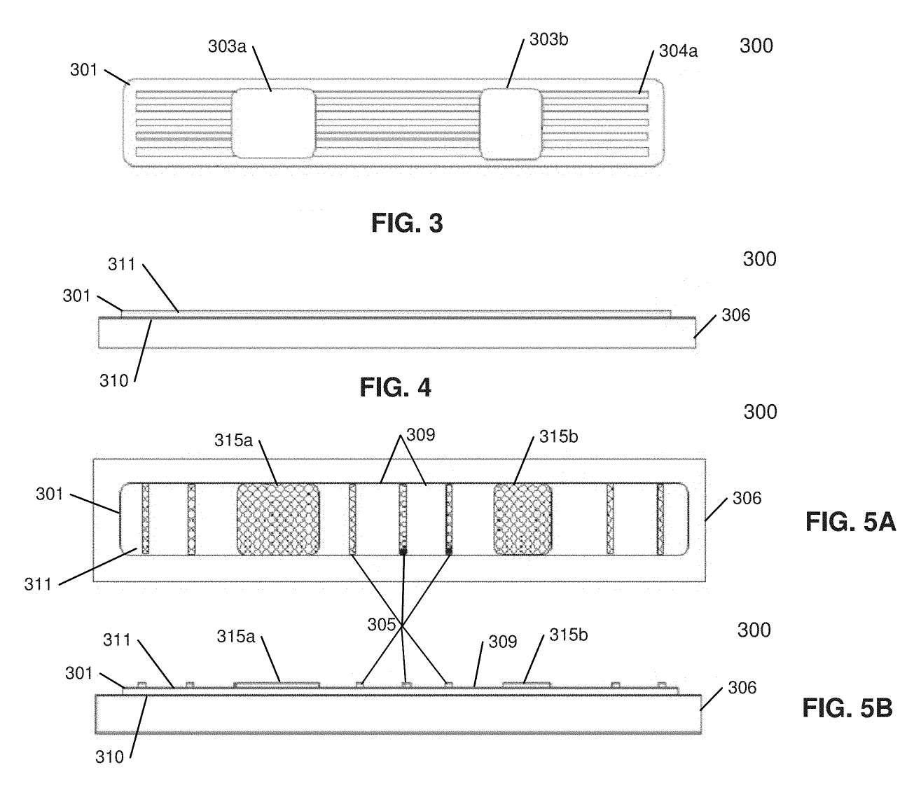

FIGS. 3 and 5A are plan views of a method of forming a stretchable electronic system 300. FIGS. 4, 5B, and 6-10 are cross-sectional views of a method of forming stretchable electronic system 300. FIGS. 3-10 describe a process flow for a PCB assembly of a stretchable electronic system 300. The process flow of FIGS. 3-10 show the method of forming a buckled flex PCB with 3D meandering trace that are embedded in an elastomer layer. Note that stretchable electronic system 300 of FIGS. 3-10 is similar to stretchable electronic system 200 of FIGS. 2A-C.

For some embodiments, FIGS. 3-10 show a method of forming buckling structures of a buckled flex PCB from a planar flex PCB (also referred to as a planar flex PCB stripe). The process flow of FIGS. 3-10 can be divided into two parts: (i) anchoring a planar flex PCB to a pre-strained elastomer at selective anchoring sites as illustrated in FIGS. 3-8, and then (ii) relaxing the strain in the elastomer to form the buckling structures on a buckled flex PCB as illustrated in FIGS. 9-10.

FIG. 3 illustrates a plan view of electronic system 300. Electronic system 300 receives planar flex PCB 301 at a system level of a PCB assembly. For some embodiments, planar flex PCB 301 includes, but is not limited to, electrical sub-systems 303a-b and planar conductive traces 304a (also referred to as straight interconnects/traces). Each of the electrical sub-systems 303a-b is formed over a rigid pad (not shown) on frontside surface 310 of planar flex PCB 301. Electrical sub-systems 303a-b may be used to assemble electrical components (not shown). Electrical sub-system 303a is connected to electrical sub-system 303b via planar conductive traces 304a.

FIG. 4 illustrates a cross-section view of electronic system 300 with rigid support 306 attached to frontside surface 310 of planar flex PCB 301. For some embodiments, the frontside surface 310 of planar flex PCB 301 is attached over, or positioned on, rigid support 306 (also referred to as a carrier substrate). The selective anchoring process of planar flex PCB 301 may be formed over rigid support 306. For example, rigid support 306 may be a rigid carrier that can be made from a stainless steel. Accordingly, for some embodiments, the backside surface 311 of planar flex PCB 301 is exposed in order to deposit an adhesive layer that forms one or more anchored sites, as shown in FIGS. 5A-B.

FIG. 5A illustrates a plan view of a selective anchoring process of backside surface 311 of planar flex PCB 301. For one embodiment, the backside surface 311 of planar flex PCB 301 includes, but is not limited to, anchored rigid pads 315a-b (also referred to as fully anchored rigid islands), stretchable segments 309 (also referred to as partially anchored stretchable segments), and anchoring sites 305 (also referred to as fixed-pitch anchoring sites). The selective anchoring process can be used to form both rigid and stretchable segments on the backside surface 311 of planar flex PCB 301. The selective anchoring process can further be employed to control the geometry (e.g., wavelength, amplitude, etc.) and mechanical properties (e.g., stretchability, compressibility, bendability, etc.) of the buckling structures of the stretchable segments 309, which is further illustrated in FIGS. 15-19.

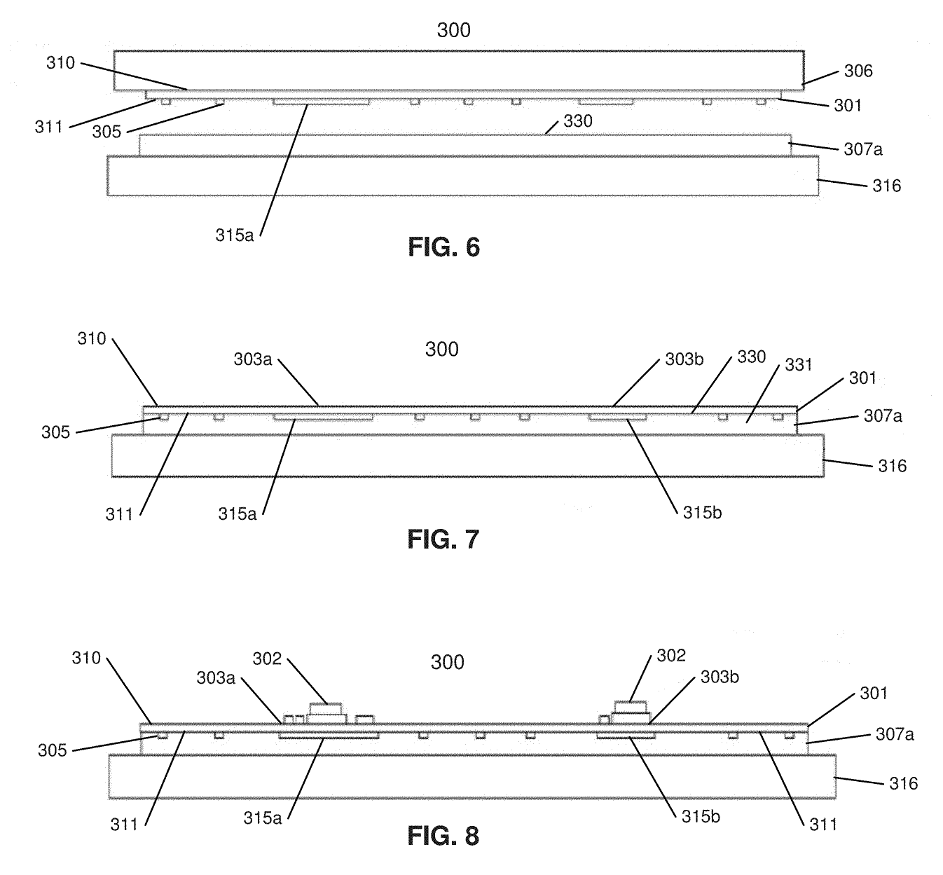

As shown in FIG. 5A, an adhesive thin layer is deposited on the backside surface 311 of planar flex PCB 301 to form anchored rigid pads 315a-b and anchoring sites 305. For one embodiment, the adhesive layer may include, but is not limited to, adhesive precursors, welds, photo-curable polymers, adhesive laminates, or the like. For some embodiments, the adhesive layer is deposited to the backside surface 311 of planar flex PCB 301 via a shadow mask process to form the rigid and fixed-pitch segments, such as rigid pads 315a-b and anchoring sites 305. For rigid segments, the planar flex PCB 301 is fully anchored to a pre-strained elastomer (e.g., pre-strained elastomer 307a of FIG. 6) such that the rigid segments remain tethered to the elastomer upon stress release. Note that fully anchored segments exhibit no buckling structures.

FIG. 5B illustrates a cross-sectional view of planar flex PCB 301 with anchoring sites 305 and rigid pads 315a-b formed over the backside surface 311 of planar flex PCB 301, as the frontside 310 of the planar flex PCB 301 is position on the rigid support 306. For some embodiment, as described above, anchoring sites 305 and rigid pads 315a-b are formed with an adhesive layer (also referred to as an anchoring thin film).

To form buckling structures for stretchable segments 309, the planar flex PCB 301 is partially anchored to the pre-strained elastomer (e.g., pre-strained elastomer 307a of FIG. 6) with anchoring sites 305 spaced at defined intervals along the length of planar flex PCB 301. Note that partially anchored segments exhibit buckling structures, such as stretchability and bendability.

FIG. 6 illustrates a cross-section view of electronic system 300 that includes planar flex PCB 301, rigid supports 306 and 316, and pre-strained elastomer 307a. For one embodiment, pre-strained elastomer is position on rigid support 316, and rigid support 306 is positioned over/on frontside surface 310 of the planar flex PCB 301. Further, as shown in FIG. 6, the backside surface 311 of planar flex PCB 301 is positioned above pre-strained elastomer 307a that is formed over rigid support 316. Accordingly, electronic system 300 forms the pre-strained elastomer 307a and then chemically activates a frontside surface 330 of the pre-strained elastomer 307. For one embodiment, the pre-strained elastomer may be formed by mechanically pulling/stretching the ends of the elastomer, heating the elastomer, and/or any other processes known in the art. Note that in a unidirectional stretchable system, the elastomer is pre-strained (stretched) in the direction of the length of the planar flex PCB 301.

FIG. 7 illustrates a cross-section view of electronic system 300 when the backside surface 311 of planar flex PCB 301 is bonded to the frontside surface 330 of pre-strained elastomer 307 after being chemically activated. As shown in FIG. 7, after rigid support 306 is removed, a lower portion 331 of the pre-strained elastomer 307a is formed. For one embodiment, rigid support 306 may be removed after bonding of the planar flex PCB 301 to pre-strained elastomer 307a is completed. For example, the rigid support 306 may be removed with a delamination process, an etching process, or any other processes known in the art

The lower portion 331 of the pre-strained elastomer 307 encapsulates the backside surface 311 of planar flex PCB 301, including anchoring sites 305 and rigid pads 315a-b. Accordingly, the frontside surface 310 of planar flex PCB 301 is exposed in order to assemble one or more electrical components (not shown) on the electrical sub-systems 303a-b of planar flex PCB 301, as shown in FIG. 8.

FIG. 8 illustrates a cross-section view of electronic system 300 when the electrical components 302 are assembled on electrical sub-systems 303a-b. As shown in FIGS. 5A-B, the electrical sub-systems 303a-b and electrical components 302 of FIG. 8 are formed over rigid pads 315a-b, which are fully anchored and will remain tethered to elastomer 307a-b upon strain release.

FIG. 9 illustrates a cross-sectional view of stretchable electronic system 400 after strain-released elastomer 307b is released from the pre-strained position. When the pre-strain is relaxed, the non-anchored flex PCB regions (i.e., stretchable segments 309) will delaminate from the strain-released elastomer 307b and form an arch (or a wave/buckle) between each pair of anchoring sites 305.

For one embodiment, stretchable electronic system 400 shows the buckling structures that were formed by the anchoring process of FIGS. 5A-B. Further, stretchable electronic system 400 illustrates the formation of buckled flex PCB 351 with 3D meandering traces 304b. As shown in FIG. 9, anchoring sites 305 are anchored on strain-released elastomer 307b to form the 3D meandering traces 304b and stretchable segments 309. Accordingly, the 3D meandering traces 304b are used to electrically connect the electrical components 302 of each of the electrical sub-systems 303a-b, while the stretchable segments 309 of the 3D meandering traces 304b can sustain stretchability.

FIG. 10 illustrates a cross-sectional view of the controlled buckled flex PCB 351 of the stretchable electronic system 400. For some embodiments, buckled flex PCB 351 includes, but is not limited to, stretchable regions 320a-c and rigid regions 321a-b. For example, stretchable regions 320a-c may include buckling structures such as stretchable segments and 3D meandering traces. Likewise, rigid regions 321a-b may include electrical sub-systems and electrical components.

In addition, stretchable electronic system 400 shows an elastomeric overmold 317 encapsulating the assembled flex PCB 351. As illustrated in FIG. 10, the elastomeric overmold 317 (also referred to as an encapsulation layer) is formed over the remainder of the stretchable electronic system 400 as to include the lower portion 331 and the upper portion 332 of the elastomer. For some embodiments, elastomeric overmold 317 may be formed from the same material as elastomer 307a-b of FIGS. 6-9. For example, the elastomeric overmold 317 may be employed to further enhance the stretchability and buckling structures of the stretchable electronic system 400. Accordingly, the process flow of FIGS. 3-10 shows the transformation of a planar flex PCB at a system level into a buckled flex PCB with 3D meandering traces. As shown in FIG. 10, the stretchable electronic system 400 is encased in elastomer 317 with buckling structures, such that the buckled flex PCB 351 can reversible arch and straighten with movement of the elastomer 317. As such, this process flow helps to enhance stretchability and facilitate high-density 3D meandering traces.

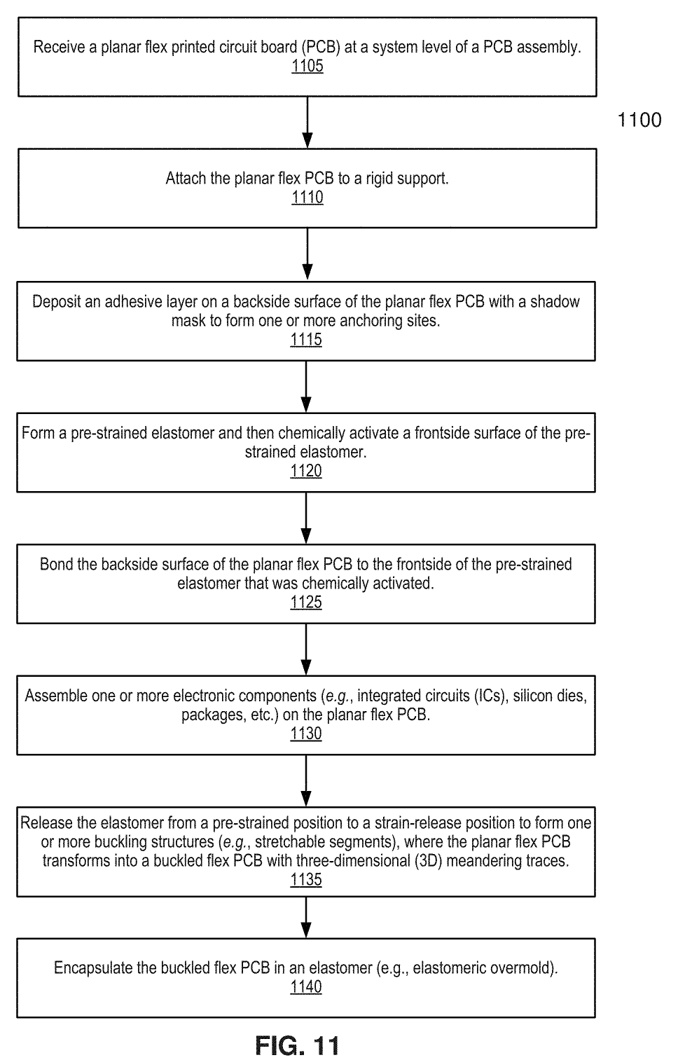

FIG. 11 shows process flow 1100 to illustrate a method of forming a stretchable electronic system that includes a buckled flex PCB. Process flow 1100 shows a method of forming a stretchable electronic system as shown in FIGS. 3-10. For one embodiment, process flow 1100 may implement a selective anchoring process as described herein. Process flow 1100 enables buckling structures and high-density 3D meandering traces in a buckled flex PCB (e.g., buckled flex PCBs 201 of FIG. 2A and 351 of FIG. 10). Process flow 1100 may also form 3D meandering traces at a system level that enable stretchable segments.

At block 1105, process flow receives planar flex PCB 301 at a system level of a PCB assembly as shown in FIG. 3. At block 1110, process flow attaches a planar flex PCB to a rigid support as shown in FIG. 4. At block 1115, process flow deposits an adhesive thin layer on a backside surface of the planar flex using a shadow mask to form one or more anchoring sites, as shown in FIGS. 5A-B.

At block 1120, process flow forms a pre-strained elastomer and then chemically activates a frontside surface of the pre-strained elastomer, as shown in FIG. 6. For example, the pre-strained elastomer may be formed over a rigid support and activated using a chemical process, a heating process, or the like.

At block 1125, process flow bonds a backside surface of the planar flex PCB to the frontside surface of the pre-strained elastomer that has been chemically activated, as shown in FIG. 7. At block 1130, process flow assembles one or more electronic components on the planar flex PCB as shown in FIG. 8. For example, the electronic components may include a foundation layer, a package, and one or more IC components (e.g., silicon dies).

At block 1135, process flow releases the elastomer from a pre-strained position to a strain-released position in order to form buckling structures, as shown in FIG. 9. Likewise, at block 1135, process flow has now assembled (or transformed) the planar flex PCB into a buckled flex PCB with 3D meandering traces and stretchable segments.

At block 1140, process flow then encapsulates the assembled buckled flex PCB in an elastomer (e.g., elastomeric overmold) as shown in FIG. 10. For one embodiment, the elastomer material that was used for the pre-strained/strained-released elastomer is deposited over the buckled flex PCB to encapsulate the remainder of the system.

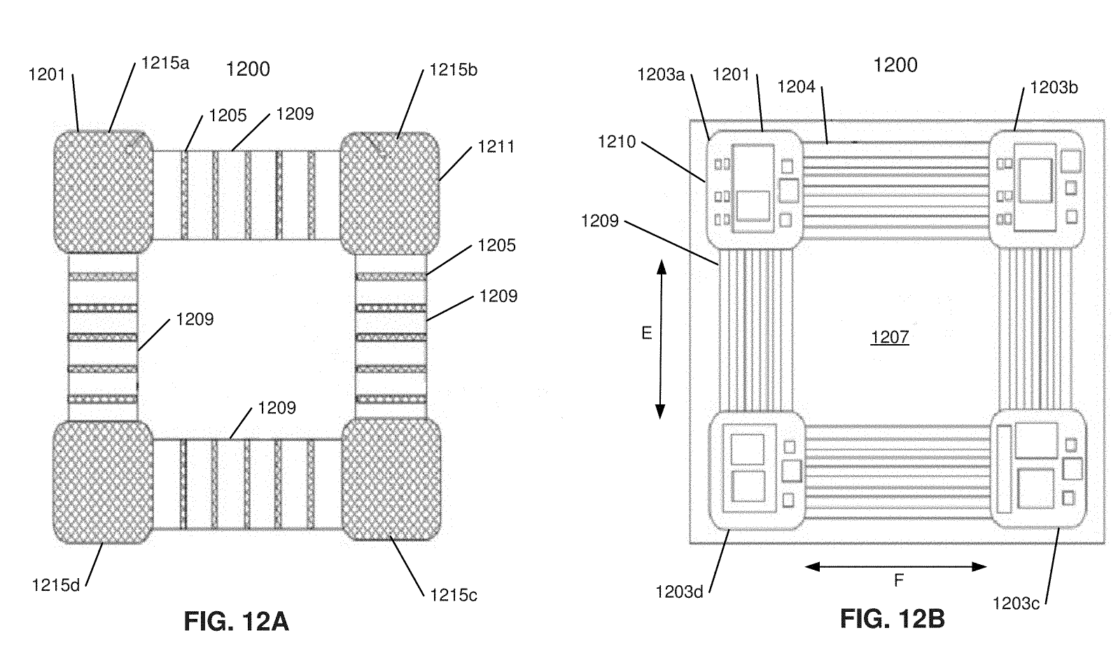

FIG. 12A is a plan view of a backside surface 1211 of a bidirectional stretchable electronic system 1200 with anchored rigid pads 1215a-d, anchoring sites 1205, and stretchable segments 1209 (or fixed-pitch anchored stretchable segments). For one embodiment, each of the rigid pads 1215a-d and anchoring sites 1205 are fully anchored using the selective anchoring process described herein.

FIG. 12B is a plan view of a frontside surface 1210 of the bidirectional stretchable electronic system 1200 at bidirectional stretched positions (as shown by arrows E and F). For one embodiment, bidirectional stretchable electronic system 1200 includes, but is not limited to, four electronic sub-systems 1203a-d connected with 3D meandering conductive traces 1204 that have stretchable segments 1209. For example, each of the electronic sub-systems 1203a-d is position over each of the anchored rigid pads 1215a-d, respectively. In addition, FIG. 12B shows a buckled flex PCB 1201 that is embedded in an elastomer 1207, where the buckled flex PCB 1201 can be stretched in two directions as shown by arrows E and F. Note that the elastomer 1207 (or elastomer substrate) is biaxially pre-strained during fabrication.

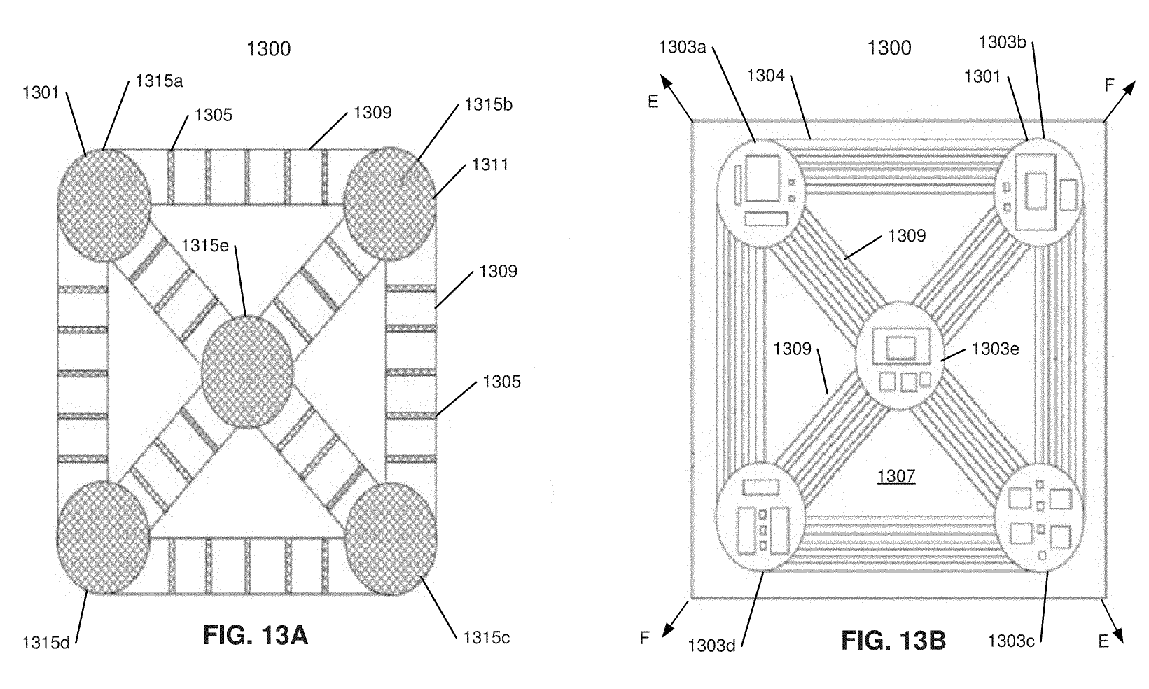

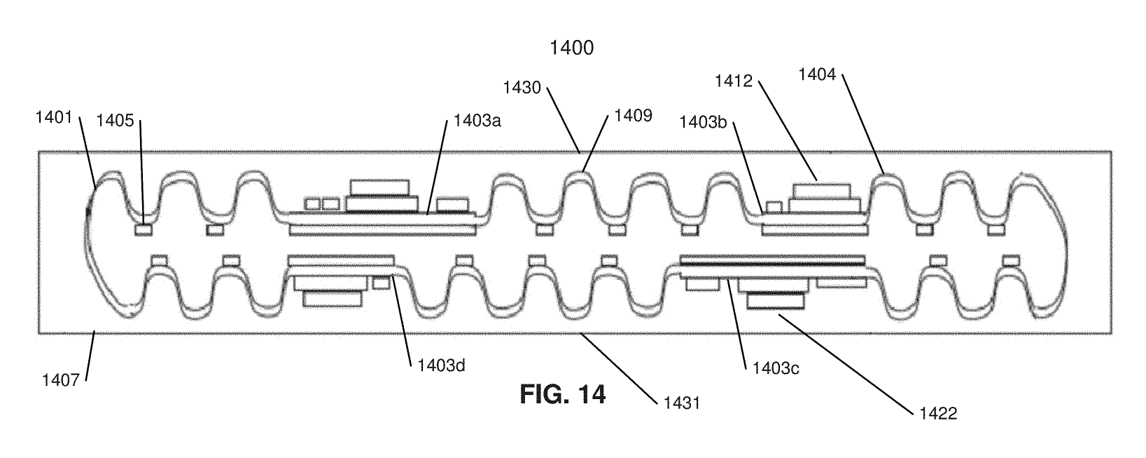

FIG. 13A is a plan view of a backside surface 1311 of an alternative bidirectional stretchable electronic system 1300 with anchored rigid pads 1315a-e, anchoring sites 1305, and stretchable segments 1309 (or fixed-pitch anchored stretchable segments). For one embodiment, each of the rigid pads 1315a-e and anchoring sites 1305 are fully anchored using the selective anchoring process described herein.

FIG. 13B is a plan view of a frontside surface 1310 of the alternative bidirectional stretchable electronic system 1300 at bidirectional stretched positions (as shown by arrows E and F). For one embodiment, bidirectional stretchable electronic system 1300 includes, but is not limited to, five electronic sub-systems 1303a-e connected with 3D meandering conductive traces 1304 that have stretchable segments 1309. For example, each of the electronic sub-systems 1303a-e is position over each of the anchored rigid pads 1315a-e, respectively. In addition, FIG. 12B shows a buckled flex PCB 1301 that is embedded in an elastomer 1307, where the buckled flex PCB 1301 can be stretched in two directions as shown by arrows E and F. Note that the elastomer 1307 (or elastomer substrate) is biaxially pre-strained during fabrication.

FIG. 14 is a cross-sectional view of a 3D stacked (or folded) stretchable electronic system 1400 with ends vertically connected to one another using buckled flex PCBs 1401 that have 3D meandering traces 1404 (or vertical interconnects). In addition, the 3D stacked stretchable electronic system 1400 includes, but is not limited to, electrical sub-systems 1403a-d, electrical components 1402, stretchable segments 1409, elastomer 1407, high power components 1412, sensors 1422, anchoring sites 1405, an air interface surface 1430, and a human contact interface surface 1431. For one embodiment, this 3D stacked stretchable electronic system 1400 helps to reduce touch skin temperature of wearables by placing high power components 1412 on the air interface surface 1430 and farther away from the human contact interface surface 1431, while the sensors 1422 are positioned on the human contact interface surface 1431 and can self-adjust to tailor to different human sizes and/or body shapes. Note that 3D stacked stretchable electronic system 1400 can be formed using a similar process flow as shown in FIGS. 3-10.

FIG. 15A is a plan view of a backside surface 1511 of a stretchable electronic system 1500 with anchoring sites 1505 on a pre-strained elastomer 1507a. FIG. 15B is a cross-sectional view of the stretchable electronic system 1500 showing one or more parameters (e.g., lengths (“L”), thickness (“h”), etc.) of a fixed-pitch anchoring pattern on pre-strained elastomer 1507a. For one embodiment, as shown in FIG. 15B, planar flex PCB 1501a is position over/on the pre-strained elastomer 1507a. For some embodiments, the anchoring sites 1505 are defined and patterned on the backside surface 1511 of the planar flex PCB 1501a, while leaving the frontside surface 1510 of the flex PCB 1501a exposed. Accordingly, the anchoring sites 1505 attach the planar flex PCB 1501a to the pre-strained elastomer 1507a.

In addition, as shown in FIG. 15B, stretchable electronic system 1500 includes at least four measured parameters for the anchoring sites that are placed at defined intervals along the PCB length. For example, the four measured parameters are the length of an anchored site (“L_{anchor}”) (e.g., L_{anchor}=100 μm), the length of a non-anchored site (“Lₙₒₙ”) (e.g., Lₙₒₙ=1000 μm), the thickness of a flex PCB stretchable segment (“h”) (e.g., h=12 μm), and the overall length (“L+ΔL”), where L is the original length of the elastomer and ΔL is the extension. Note that the stretchability of the stretchable electronic system 1500 can be increased by applying a larger pre-strain to the elastomer during fabrication, where the pre-strain applied to elastomer is defined as εₚᵣₑ=ΔL/L (e.g., εₚᵣₑ=50%).

FIG. 16 is a cross-sectional view of stretchable electronic system 1500 upon strain release. FIG. 16 shows a buckled flex PCB 1501b with 3D meandering traces 1504 and stretchable segments 1509 positioned on a strain-released elastomer 1507b. Note that a strain-released elastomer as used herein is the same elastomer as a pre-strained elastomer, however the elastomer is differentiated to show whether it's stretched or released.

In addition, as shown in FIG. 16, stretchable electronic system 1500 includes at least one or more parameters to show the geometry of the buckled flex PCB 1501b after strain relaxation. For example, the one or more parameters are a wavelength of a buckling structure (“λ”), a sum of the anchored and non-anchored sites (“Lₜₒₜₐₗ^{”}), a critical strain for buckling (ε_{c}), a buckling amplitude (“A”) that contributes to the total thickness of the system, and a maximum strain in the buckled flex PCB at the bending strain that occurs at the wave peak (εₚₑₐₖ). Note that this strain value may be reduced by constructing the conductive traces in the neutral mechanical plane of the flex PCB.

Further, the wavelength of a buckling structure (“λ”) can be defined as λ=(L_{anchor}/(1+εₚᵣₑ)) (e.g., λ=667 μm). The sum of the anchored and non-anchored sites (“Lₜₒₜₐₗ”) can be defined as Lₜₒₜₐₗ=(((L_{anchor}/(1+εₚᵣₑ))+Lₙₒₙ)) (e.g., Lₜₒₜₐₗ=767 μm). The critical strain for buckling (ε_{c}) can be defined as ε_{c}=((h²π²)/(12(0.5λ)²)) (e.g., ε_{c}=0.11%). The buckling amplitude (“A”) can be defined as A=(4/π)√((0.5λ)(0.5Lₜₒₜₐₗ)(εₚᵣₑ−ε_{c})))) (e.g., A=342 μm). The wave peak can be defined as εₚₑₐₖ=((hλ)/(0.5λ)²)(√(0.5λ)(0.5Lₜₒₜₐₗ)(εₚᵣₑ)))) (e.g., A=9.1%).

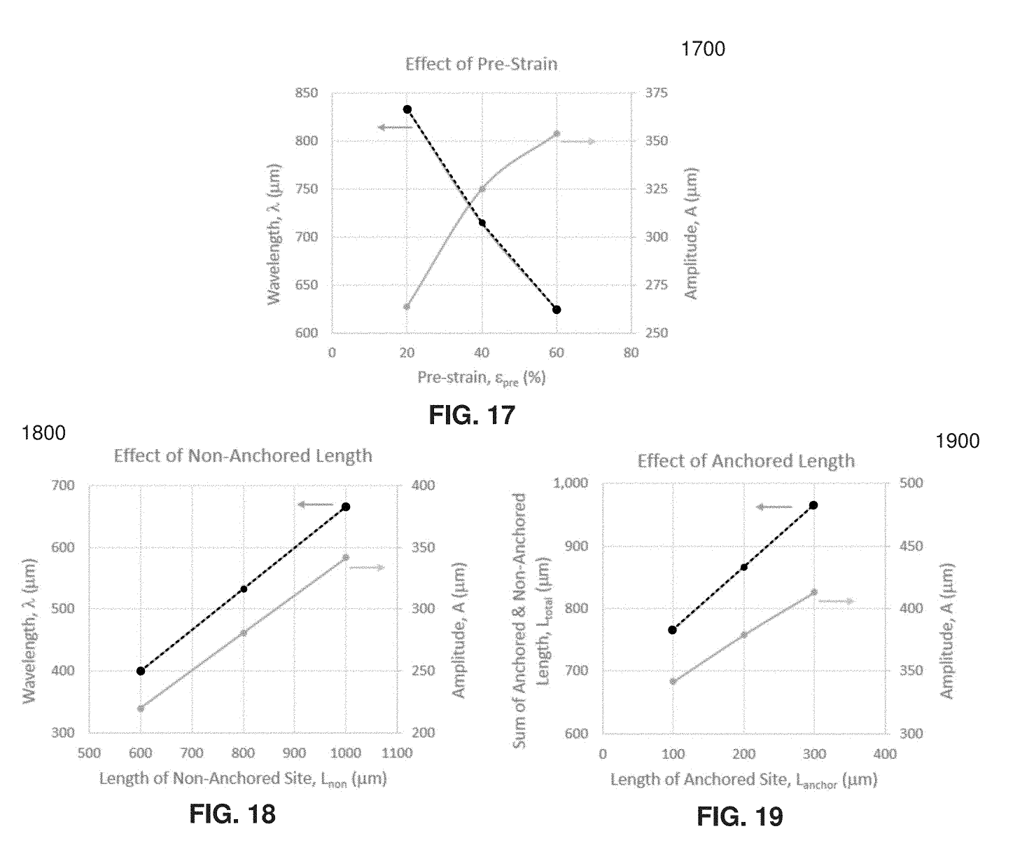

FIG. 17 is a graph 1700 illustrating a pre-strained elastomer using a stretchable electronic system as shown in FIGS. 15A-B. Graph 1700 also shows the effect of the pre-strained elastomer (εₚᵣₑ) with the following set parameters: a thickness of a stretchable segment of a buckled flex PCB (h)=12 μm, a length of an anchored site (L_{anchor})=100 μm, and a length of a non-anchored site (Lₙₒₙ)=1000 μm. Furthermore, graph 1700 shows a dashed line that illustrates a wavelength of a buckling structure (“Wavelength, λ (μm)”) versus a pre-strained elastomer (“Pre-strain, εₚᵣₑ (%)”); and a solid line that illustrates a buckling amplitude (“Amplitude, A (μm)”) versus a pre-strained elastomer (“Pre-strain, εₚᵣₑ (%)”).

FIG. 18 is a graph 1800 illustrating a non-anchored length of a periodic anchoring pattern using a stretchable electronic system as shown in FIGS. 15A-B. Graph 1800 also shows the effect of the non-anchored length of the periodic anchoring pattern (Lₙₒₙ) with the following set parameters: a thickness of a stretchable segment of a buckled flex PCB (h)=12 μm, a length of an anchored site (L_{anchor})=100 μm, and a pre-strained elastomer (εₚᵣₑ)=50%. Furthermore, graph 1800 shows a dashed line that illustrates a wavelength of a buckling structure (“Wavelength, λ (μm)”) versus a length of a non-anchored site (“Length of Non-Anchored Site, Lₙₒₙ (μm)”); and a solid line that illustrates a buckling amplitude (“Amplitude, A (μm)”) versus a length of a non-anchored site (“Length of Non-Anchored Site, Lₙₒₙ (μm)”).

FIG. 19 is a graph 1900 illustrating an anchored length of a periodic anchoring pattern using a stretchable electronic system as shown in FIGS. 15A-B and 16. Graph 1900 also shows the effect of the anchored length of the periodic anchoring pattern (L_{anchor}) with the following set parameter: a thickness of a stretchable segment of a buckled flex PCB (h)=12 μm, a length of a non-anchored site (Lₙₒₙ)=1000 μm, and a pre-strained elastomer (εₚᵣₑ)=50%. Furthermore, graph 1900 shows a dashed line that illustrates a total length of the sum of the anchored and non-anchored length (“Sum of Anchored & Non-Anchored Length, Lₜₒₜₐₗ (μm)”) versus a length of an anchored site (“Length of Anchored Site, L_{anchor} (μm)”; and a solid line that illustrates a buckling amplitude (“Amplitude, A (μm)”) versus a length of an anchored site (“Length of Anchored Site, L_{anchor} (μm)”).

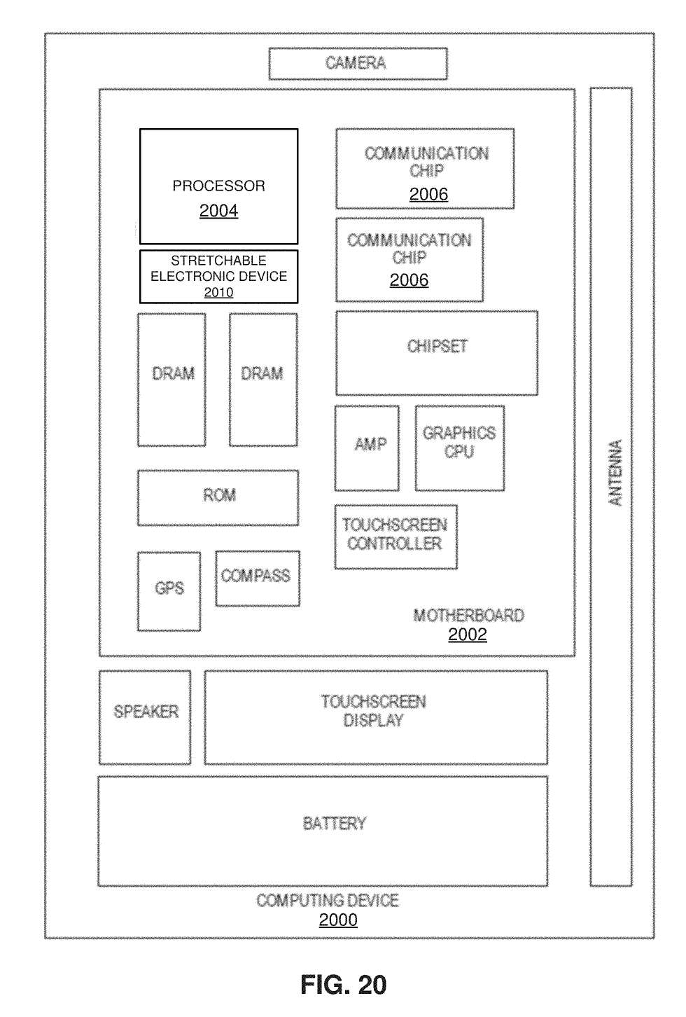

FIG. 20 is a schematic block diagram illustrating a computer system that utilizes a foundation layer. FIG. 20 illustrates an example of computing device 2000. Computing device 2000 houses motherboard 2002. Motherboard 2002 may include a number of components, including but not limited to processor 2004, stretchable electronic device 2010, and at least one communication chip 2006. Processor 2004 is physically and electrically coupled to motherboard 2002. For some embodiments, at least one communication chip 2006 is also physically and electrically coupled to motherboard 2002. For other embodiments, at least one communication chip 2006 is part of processor 2004.

Depending on its applications, computing device 2000 may include other components that may or may not be physically and electrically coupled to motherboard 2002. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 2006 enables wireless communications for the transfer of data to and from computing device 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 2006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

Processor 2004 of computing device 2000 includes an integrated circuit die packaged within processor 2004. Stretchable electronic device 2010 may include a buckled flex PCB as described herein. For certain embodiments, the buckled flex PCB of stretchable electronic device 2010 may be packaged with one or more electrical sub-systems electrically connected by a plurality of 3D conductive traces. Note that stretchable electronic device 2010 may be a single component, a subset of components, or an entire computing device/system, as such stretchable electronic device may be limited to component 2010 and/or any other component that requires stretchability (e.g., the overall computing device 2000).

For some embodiments, the integrated circuit die may be packaged with one or more devices on stretchable electronic device 2010 that includes a thermally stable RFIC and antenna for use with wireless communications. The term “processor” may refer to any device or portion of a device that processes electronic data from registers and/or memory to transform that electronic data into other electronic data that may be stored in registers and/or memory.

At least one communication chip 2006 also includes an integrated circuit die packaged within the communication chip 2006. For some embodiments, the integrated circuit die of the communication chip may be packaged with one or more devices on stretchable electronic device 2010, as described herein, to provide a buckled flex PCB with elasticity, stretchability, and/or bendability.

The following examples pertain to further embodiments. The various features of the different embodiments may be variously combined with some features included and others excluded to suit a variety of different applications.

The following examples pertain to further embodiments:

For one embodiment, a microelectronic device, comprising: a flex printed circuit board (PCB) having two or more electrical sub-systems that are electrically coupled by a plurality of conductive traces; a plurality of anchoring sites formed on a backside surface of the flex PCB; and an elastomer encapsulating the flex PCB, the two or more electrical sub-systems, and the plurality of conductive traces.

For one embodiment of the microelectronic device, wherein the flex PCB is a buckled flex PCB.

For one embodiment of the microelectronic device, wherein the flex PCB includes a plurality of stretchable segments.

For one embodiment of the microelectronic device, wherein each stretchable segment is formed between a pair of anchoring sites.

For one embodiment of the microelectronic device, further comprising two or more rigid pads formed on the backside surface of the flex PCB.

For one embodiment of the microelectronic device, wherein the electrical sub-systems are formed on a frontside surface of the flex PCB.

For one embodiment of the microelectronic device, wherein the electrical sub-systems are positioned above the rigid pads.

For one embodiment of the microelectronic device, wherein each of the electrical sub-systems includes a first plurality of conductive traces at one end and a second plurality of conductive traces at another end.

For one embodiment of the microelectronic device, wherein each of the electrical sub-systems includes at least one of a package substrate, a printed circuit board, and one or more electrical components.

For one embodiment of the microelectronic device, wherein the one or more electrical components includes a semiconductor die.

For one embodiment of the microelectronic device, wherein the semiconductor die is at least one of a flip-chip and a wire-bonded die.

For one embodiment of the microelectronic device, wherein the plurality of conductive traces include at least one of two-dimensional (2D) conductive traces and three-dimensional (3D) conductive traces, and wherein the plurality of conductive traces are formed with a plurality of shapes or a plurality of sizes.

For one embodiment of the microelectronic device, wherein the 3D conductive traces are 3D meandering traces.

For one embodiment of the microelectronic device, further comprising a hard overmold layer formed over each of the electrical sub-systems.

For one embodiment of the microelectronic device, wherein the flex PCB is stretched in at least one of a unidirectional axis and a bidirectional axis, and wherein the buckled flex PCB includes one or more fully anchored segments and one or more partially anchored segments.

For another embodiment, a microelectronic device comprising: a first flex PCB having a first plurality of electrical sub-systems that are electrically coupled by a first plurality of conductive traces; a second flex PCB having a second plurality electrical sub-systems that are electrically coupled by a second plurality of conductive traces, wherein the first flex PCB is connected to the second flex PCB with the first and second plurality of conductive traces; a plurality of anchoring sites formed on a backside surface of the first and second flex PCBs; and an elastomer encapsulating the first and second plurality of electrical sub-systems, the first and second plurality of conductive traces, and the first and second flex PCBs that are connected to each other.

For one embodiment of the microelectronic device, wherein the first and second flex PCBs are connected to form a 3D stacked flex PCB, wherein the 3D stacked flex PCB includes a plurality of stretchable segments, and wherein each stretchable segment is formed between a pair of anchoring sites.

For one embodiment of the microelectronic device, further comprising: a plurality of rigid pads formed on the backside surface of the flex PCB, wherein the first and second plurality of electrical sub-systems are positioned above the plurality of rigid pads; and a hard overmold layer formed over each of the electrical sub-systems.

For some embodiments, a method of forming a microelectronic device, comprising: attaching a flex printed circuit board (PCB) over a rigid support, wherein the flex PCB includes two or more electrical sub-systems that are electrically coupled by a plurality of conductive traces; depositing an adhesive layer over a backside surface of the flex PCB to form a plurality of anchoring sites; bonding a frontside surface of an elastomer to the backside surface of the flex PCB; releasing, at a pre-strain position, the elastomer to form one or more stretchable segments on the flex PCB; and forming an encapsulation layer over the flex PCB, the elastomer, the two or more electrical sub-systems, and the plurality of conductive traces.

For another embodiment, the method further comprising assembling one or more electronic components on each of the electrical sub-systems of the flex PCB.

For another embodiment, the method further comprising stretching the elastomer to the pre-strain position and activating the frontside surface of the pre-strained elastomer, prior to bonding the frontside surface of the elastomer to the backside surface of the flex PCB.

For one embodiment of the method, wherein the flex PCB is a buckled flex PCB.

For one embodiment of the method, wherein each stretchable segment is formed between a pair of anchoring sites.

For one embodiment, the method further comprising forming two or more rigid pads over the backside surface of the flex PCB with the deposited adhesive layer.

For one embodiment of the method, wherein the plurality of conductive traces include at least one of two-dimensional (2D) conductive traces and three-dimensional (3D) conductive traces, and wherein the 3D conductive traces are 3D meandering traces.

For one embodiment of the method, wherein the plurality of conductive traces are formed with a plurality of shapes or a plurality of sizes.

For one embodiment of the method, wherein the flex PCB is stretched in at least one of a unidirectional axis and a bidirectional axis.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

1. A microelectronic device, comprising:
a flex printed circuit board (PCB) having two or more electrical sub-systems that are electrically coupled by a plurality of conductive traces;
a plurality of anchoring sites formed on a backside surface of the flex PCB; and
an elastomer encapsulating the flex PCB, the two or more electrical sub-systems, and the plurality of conductive traces.

2. The microelectronic device of claim 1, wherein the flex PCB is a buckled flex PCB.

3. The microelectronic device of claim 1, wherein the flex PCB includes a plurality of stretchable segments.

4. The microelectronic device of claim 3, wherein each stretchable segment is formed between a pair of anchoring sites.

5. The microelectronic device of claim 3, wherein the electrical sub-systems are positioned above the rigid pads.

6. The microelectronic device of claim 1, wherein each of the electrical sub-systems includes a first plurality of conductive traces at one end and a second plurality of conductive traces at another end.

7. The microelectronic device of claim 1, wherein each of the electrical sub-systems includes at least one of a package substrate, a printed circuit board, and one or more electrical components.

8. The microelectronic device of claim 7, wherein the one or more electrical components includes a semiconductor die.

9. The microelectronic device of claim 8, wherein the semiconductor die is at least one of a flip-chip and a wire-bonded die.

10. The microelectronic device of claim 1, wherein the plurality of conductive traces include at least one of two-dimensional (2D) conductive traces and three-dimensional (3D) conductive traces, and wherein the plurality of conductive traces are formed with a plurality of shapes or a plurality of sizes.

11. The microelectronic device of claim I0, wherein the 3D conductive traces are 3D meandering traces.

12. The microelectronic device of claim 1, further comprising a hard overmold layer formed over each of the electrical sub-systems.

13. The microelectronic device of claim 1, wherein the flex PCB is stretched in at least one of a unidirectional axis and a bidirectional axis, and wherein the buckled flex PCB includes one or more fully anchored segments and one or more partially anchored segments.

14. A microelectronic device, comprising:
a first flex PCB having a first plurality of electrical sub-systems that are electrically coupled by a first plurality of conductive traces;
a second flex PCB having a second plurality of electrical sub-systems that are electrically coupled by a second plurality of conductive traces, wherein the first flex PCB is connected to the second flex PCB with the first and second plurality of conductive traces;
a plurality of anchoring sites formed on a backside surface of the first and second flex PCBs; and
an elastomer encapsulating the first and second plurality of electrical sub-systems, the first and second plurality of conductive traces, and the first and second flex PCBs that are connected to each other.

15. The microelectronic device of claim 14, wherein the first and second flex PCBs are connected to form a 3D stacked flex PCB, wherein the 3D stacked flex PCB includes a plurality of stretchable segments, and wherein each stretchable segment is formed between a pair of anchoring sites.

16. The microelectronic device of claim 14, further comprising:
a plurality of rigid pads formed on the backside surface of the flex PCB, wherein the first
and second plurality of electrical sub-systems are positioned above the plurality of rigid pads; and
a hard overmold layer formed over each of the electrical sub-systems.

17. A method of forming a microelectronic device, comprising:
attaching a flex printed circuit board (PCB) over a rigid support, wherein the flex PCB includes two or more electrical sub-systems that are electrically coupled by a plurality of conductive traces;
depositing an adhesive layer over a backside surface of the flex PCB to form a plurality of anchoring sites;
bonding a frontside surface of an elastomer to the backside surface of the flex PCB;
releasing, at a pre-strain position, the elastomer to form one or more stretchable segments on
the flex PCB; and
forming an encapsulation layer over the flex PCB, the elastomer, the two or more electrical sub-systems, and the plurality of conductive traces.

18. The method of claim 17, further comprising assembling one or more electronic components on each of the electrical sub-systems of the flex PCB.

19. The method of claim 17, further comprising stretching the elastomer to the pre-strain position and activating the frontside surface of the pre-strained elastomer, prior to bonding the frontside surface of the elastomer to the backside surface of the flex PCB.

20. The method of claim 17, wherein the flex PCB is a buckled flex PCB.

21. The method of claim 17, wherein each stretchable segment is formed between a pair of anchoring sites.

22. The method of claim 17, further comprising forming two or more rigid pads over the backside surface of the flex PCB with the deposited adhesive layer.

23. The method of claim 17, wherein the plurality of conductive traces include at least one of two-dimensional (2D) conductive traces and three-dimensional (3D) conductive traces, and wherein the 3D conductive traces are 3D meandering traces.

24. The method of claim 17, wherein the plurality of conductive traces are formed with a plurality of shapes or a plurality of sizes.

25. The method of claim 17, wherein the flex PCB is stretched in at least one of a unidirectional axis and a bidirectional axis.
